(19) United States
(12) Patent Application Publication
(10) Pub. No.: US 2007/0165476 A1
(43) Pub. Date: Jul. 19, 2007

(54) CLOCK SIGNAL GENERATING CIRCUIT

(75) Inventor: Yasuhiro Takai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/621,025

(22) Filed: Jan. 8, 2007

(30) Foreign Application Priority Data
Jan. 16, 2006 (JP) 2006-007271

(51) Int. Cl. G11C 7/00

(52) U.S. Cl. 365/221

(57) ABSTRACT

Each of identically configured logic inverter circuits 10a, 10b, 10c, and 10d comprises a PMOS transistor MP1 (abbreviated as MP1 hereinafter), and NMOS transistors MN1 and MN2 (abbreviated as MN1 and MN2 hereinafter). Gates of MP1 and MN1 are connected to input terminal IN1, gate of MN2 is connected to input terminal IN2, drains of MP1 and MN1 are connected to an output terminal OUT, source of MN1 is connected to the drain of MN2, source of MP1 is connected to a controllable power supply VC, and source of MN2 is grounded. Input terminals IN1 and IN2 of logic inverter circuits 10a, 10b, 10c, and 10d are connected to output terminals OUT of the logic inverter circuits 10b and 10c, 10c and 10d, 10d and 10a, and 10a and 10b respectively. High-speed four-phase clock signals are generated.

### FIELD OF THE INVENTION

The present invention relates to a clock signal generating circuit, and particularly to a clock signal generating circuit that generates four-phase clock signals.

### BACKGROUND OF THE INVENTION

In high-speed data transfer technology and on-chip high-speed clock distribution technology, a method using four-phase clock signals whose phases are shifted from one to the next (sequentially) by 90 degrees is known. For instance, in double data rate source synchronous data transfer, a data signal and a strobe signal are sent at the same phase, and the data is latched, delaying the phase of the strobe signal by 90 degrees at a receiving end. Further, the four-phase clock signals with a phase difference of 90 degrees are used in clock distribution technologies in which the operating frequency of a clock signal is one half of the data transfer speed, i.e., one quarter of the data operating frequency since the clock line shared by a plurality of data lines has a heavy load.

As a method for generating such four-phase clock signals, a voltage-controlled oscillator circuit (VCO) combining a three-stage ring oscillator, where controlled inverters 100a, 100b, and 100c are connected in a cascade fashion to a power supply voltage VC, and a frequency divider circuit 101 as shown in FIG. 5 is conventionally and widely known. In other words, an output signal R0 of the ring oscillator is supplied to the frequency divider circuit 101, which divides the signal by 4, and clock signals C101, C102, C103, and C104 whose phases are shifted from one to next by 90 degrees are outputted. The power supply voltage VC is adjusted by a phase frequency detection circuit PFD, a charge pump CP, and a loop filter LF (all not shown in the drawing) so that the clock signal C101 is synchronized to an external clock signal Ex. As a result, the four-phase clock signals having each 90-degree phase difference based on the external signal as an oscillation period of the ring oscillator can be generated.

Next, the timing of the signals generated by the clock signal generating circuit will be described. FIG. 6 is a timing chart of the signals generated by the clock signal generating circuit shown in FIG. 5. In FIG. 6, the output signal R0 is divided by 4, and the clock signals C101, C102, C103, and C104 whose phases are shifted from one to the next by 90 degrees are generated. Further, the clock signal C101 is synchronized to the external clock Ex. When the propagation time of the inverters 100a, 100b, and 100c constituting the ring oscillator is tPD1, the oscillation period T0 to T8 of the three-stage ring oscillator is 6tPD1. In other words, the practical operating frequency of the four-phase clock signals is 1/(6tPD1). Since the ring oscillator is constituted by the inverters, which are the smallest logical units, tPD1 is the minimum propagation time specific to the process.

However, the practical operating frequency of 1/(6tPD1) does not meet the demand for high-speed operation in the clock signal generating circuit in FIG. 5. Furthermore, since the ring oscillator operates at a frequency four times the practical operating frequency of the four-phase clock signals, this operating speed becomes a bottleneck for realizing a high-speed operation.

A voltage-controlled oscillator circuit attempted to eliminate this bottleneck for high-speed operation is disclosed in Patent Document 1. This voltage-controlled oscillator circuit generates four-phase clocks by combining RS flip-flops and constant current driving inverters, and when the respective propagation time is tPD2 and tPD3, the practical operating frequency of the four-phase clocks is 1/(tPD2+tPD3). Assuming that the RS flip-flops be minimally constituted by cross-connected NAND circuits, tPD2 is the propagation time of one stage of the NAND circuit. tPD2 and tPD3 are larger than tPD1, but tPD2+tPD3 is smaller than 6tPD1. Therefore the practical frequency is enhanced.

[Patent Document 1]

Japanese Patent Kokai Publication No. JP-A-10-126224

### SUMMARY OF THE DISCLOSURE

The disclosure of the above Patent Document 1 is herein incorporated by reference thereto. Meanwhile according to the analysis by the present invention, since the propagation time tPD3 of the constant current driving inverters in the voltage-controlled oscillator circuit disclosed in Patent Document 1 is much slower than the propagation time tPD1 of the simple inverter circuit, it would be thought that there would be room for improvement for the maximum operating frequency. However, the improvement has been considered to be difficult, and the issue has been left neglected without much research done. Up until this point, no attempt has been made to generate a clock signal with still a higher operating frequency.

According to a first aspect of the present invention there is provided a clock signal generating circuit comprising first to fourth logic inverter circuits. The first to fourth logic inverter circuits are respectively connected between first and second power supplies, and respectively comprise first and second input terminals and an output terminal. In each of the logic inverter circuits, the output terminal is at a second level when the first input terminal is at a first level, whereas the output terminal is at a first level when the first and the second input terminals are at the second level. Further, the first input terminals of the first to fourth logic inverter circuits are connected to the output terminals of the second, the third, the fourth, and the first logic inverter circuits respectively, and the second input terminals of the first to fourth logic inverter circuits are connected to the output terminals of the third, the fourth, the first, and the second logic inverter circuits respectively.

In a first development of the clock signal generating circuit, each of the first to fourth logic inverter circuits comprises a first MOS transistor of a first conductivity type and first and second MOS transistors of a second conductivity type; a gate of the first MOS transistor of the first conductivity type and a gate of the first or the second MOS transistor of the second conductivity type are connected to the first input terminal; a gate of the other MOS transistor of the second conductivity type is connected to the second input terminal; a drain of the first MOS transistor of the first conductivity type and a drain of the first MOS transistor of the second conductivity type are connected to the output terminal; a source of the first MOS transistor of the second conductivity type is connected to a drain of the second MOS transistor of the second conductivity type; a source of the first MOS transistor of the first conductivity type is connected to the first power supply; and a source of the second MOS transistor of the second conductivity type is connected to the second power supply.

In a second development of the clock signal generating circuit, each of the first to fourth logic inverter circuits further comprises a second MOS transistor of the first conductivity type having its source connected to the source of the first MOS transistor of the first conductivity type, its drain connected to the drain of the first MOS transistor of the first conductivity type, and its gate connected to the second input terminal.

According to a second aspect of the present invention there is provided a clock signal generating circuit comprising first to fourth two-input NAND circuits connected between first and second power supplies. One of input terminals of each of the first to fourth two-input NAND circuits is connected to an output terminal of the second, the third, the fourth, and the first two-input NAND circuits respectively, and the other input terminal of each of the first to fourth two-input NAND circuits are connected to an output terminal of the third, the fourth, the first, and the second two-input NAND circuits respectively. In a development, the two-input NAND circuits may be replaced by two-input NOR circuits. According to a third aspect of the present invention, there is provided a voltage-controlled oscillator comprising the clock generating circuit aforementioned herein.

The meritorious effects of the present invention are summarized as follows.

According to the present invention, high-speed four-phase clock signals can be generated by combining four simply configured logic inverter circuits.

### BRIEF DESCRIPTIONS OF THE DRAWINGS

FIG. 1 is a circuit diagram of a clock signal generating circuit relating to a first example of the present invention.

FIG. 2 is a timing chart illustrating the operation of the clock signal generating circuit relating to the first example of the present invention.

FIG. 3 is a circuit diagram of a clock signal generating circuit relating to a second example of the present invention.

FIG. 4 is a circuit diagram of a clock signal generating circuit relating to a third example of the present invention.

FIG. 5 is a circuit diagram of a voltage-controlled oscillator circuit in which a conventional three-stage ring oscillator and a frequency divider circuit are combined.

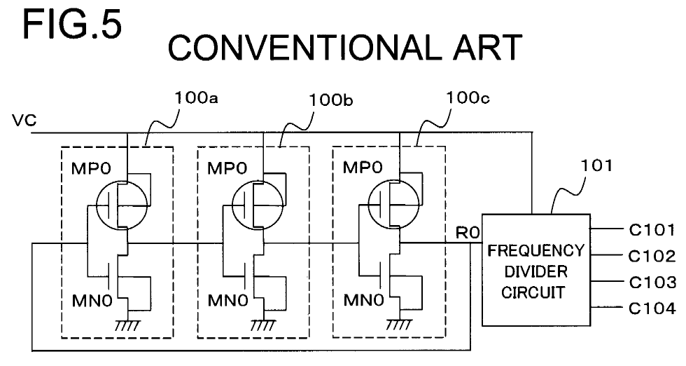

FIG. 6 is a timing chart of signals generated by a conventional voltage-controlled oscillator circuit, as analyzed by the present invention.

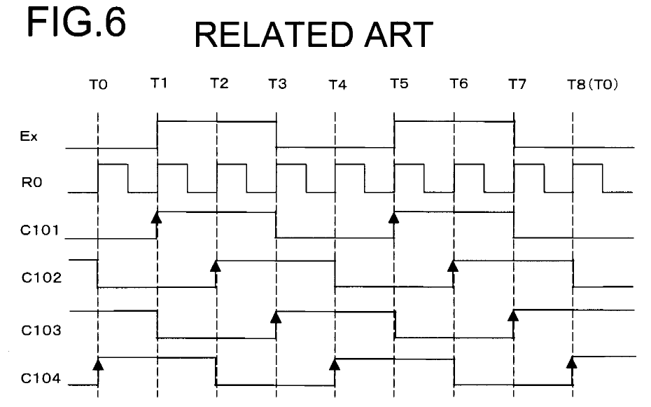

### MODES OF THE INVENTION

A clock generation circuit relating to an example of the present invention comprises first to fourth logic inverter circuits. The first to fourth logic inverter circuits respectively comprise a PMOS transistor and first and second NMOS transistors, a gate of the PMOS transistor and a gate of the first or the second NMOS transistor are connected to form a first input terminal, a gate of the other NMOS transistor becomes a second input terminal, and a drain of the PMOS transistor and a drain of the first NMOS transistor are connected to form an output terminal. Further, a source of the first NMOS transistor and a drain of the second NMOS transistor are connected, a source of the PMOS transistor is connected to a voltage-controlled power supply, and a source of the second NMOS transistor is grounded. Each of the first input terminals of the first to fourth logic inverter circuits is connected to an output terminal of the second, the third, the fourth, and the first logic inverter circuits respectively, each of the second input terminals of the first to fourth logic inverter circuits is connected to an output terminal of the third, the fourth, the first, and the second logic inverter circuits respectively.

The clock signal generating circuit configured as described above is equivalent to a circuit in which four simply configured logic inverter circuits are combined and two RS flip-flops are connected in a crossed fashion (termed herein “cross-connected”), and it becomes a voltage-controlled oscillation circuit by controlling the power supply voltage of the logic inverter circuits. Further, clock signals whose phases are shifted from one to next by 90 degrees are respectively obtained from the output terminals of the four logic inverter circuits, therefore the circuit functions as a four-phase clock generation circuit in which the phase difference is small, only twice the propagation time of the MOS transistor. Examples will be described in detail with reference to the drawings.

### EXAMPLE 1

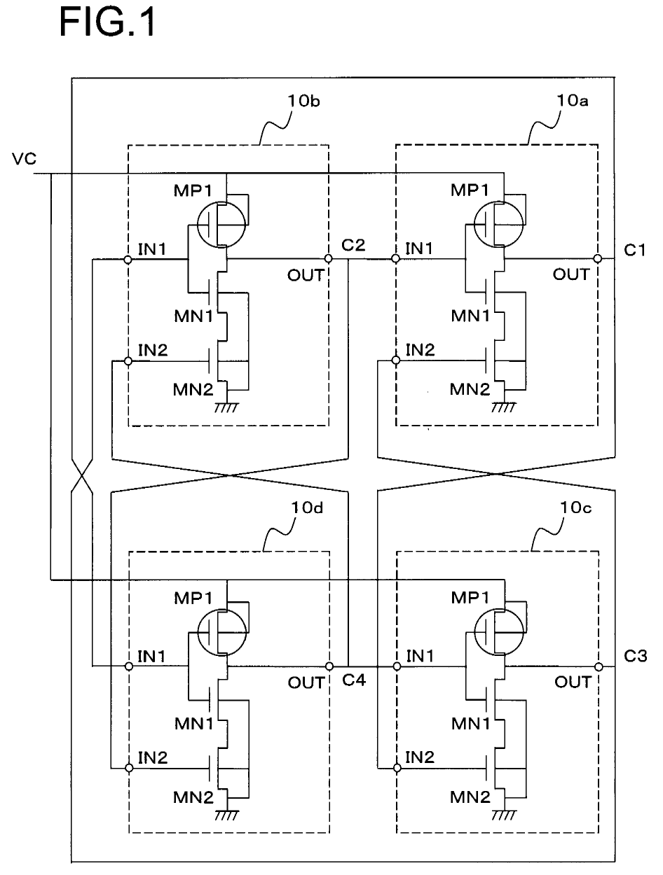

FIG. 1 is a circuit diagram of a clock signal generating circuit relating to a first example of the present invention. In FIG. 1, the clock signal generating circuit comprises logic inverter circuits 10a, 10b, 10c, and 10d, which are identically configured. Each logic inverter circuit comprises a PMOS transistor MP1 and NMOS transistors MN1 and MN2. The gate of the PMOS transistor MP1 and the gate of the NMOS transistor MN1 are connected to an input terminal IN1, and the gate of the NMOS transistor MN2 is connected to an input terminal IN2. Furthermore, the drain of the PMOS transistor MP1 and the drain of the NMOS transistor MN1 are connected to an output terminal OUT. The source of the NMOS transistor MN1 and the drain of the NMOS transistor MN2 are connected, the source of the PMOS transistor MP1 is connected to a power supply VC, and the source of the NMOS transistor MN2 is grounded. Note that the voltage of the power supply VC is varied by a voltage control circuit not shown in the drawing.

Each of the input terminals IN1 of the logic inverter circuits 10a, 10b, 10c, and 10d is connected to an output terminal OUT of the logic inverter circuits 10b, 10c, 10d, and 10a respectively. Further, each of the input terminals IN2 of the logic inverter circuits 10a, 10b, 10c, and 10d is connected to an output terminal OUT of the logic inverter circuits 10c, 10d, 10a, and 10b respectively.

The clock signal generating circuit configured as described above is equivalent to a circuit in which the logic inverter circuits 10a and 10c constitute one RS flip-flop, the logic inverter circuits 10b and 10d constitute another RS flip-flop, and the two RS flip-flops are cross-connected. The clock signal generating circuit becomes a voltage-controlled oscillator circuit by controlling the voltage of the power supply VC. Further, clock signals C1, C2, C3, and C4 whose phases are shifted from one to the next by 90 degrees are respectively obtained from the output terminals OUT of the logic inverter circuits 10a, 10b, 10c, and 10d, therefore it functions as a four-phase clock generation circuit.

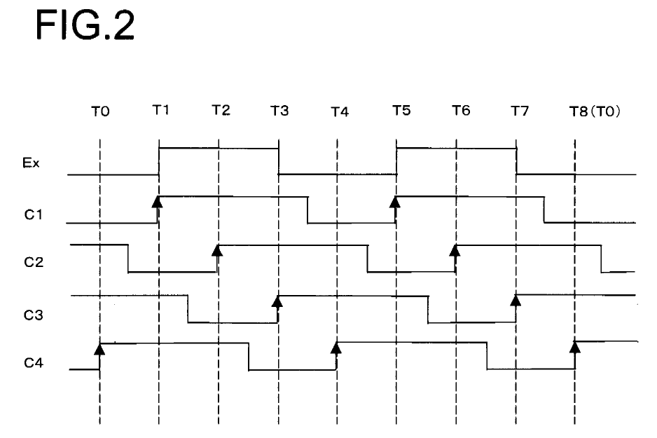

Next, the operation of the clock signal generating circuit will be described. FIG. 2 is a timing chart illustrating the operation of the clock signal generating circuit relating to the first example of the present invention. In FIG. 2, each operation at timings T0 to T8 is the same (only the symbols are different), and the timings T0 to T1 are described here. The clock signal C1 is at a low level, the clock signal C2 is at a high level, the clock signal C3 is at a high level, and the clock signal C4 is changing from a low level to a high level (the timing T0). The clock signals C3 and C4, received by the logic inverter circuit 10b that outputs the clock signal C2, are both at a high level. Therefore, the NMOS transistors MN 1 and MN2 are turned on, and the clock signal C2 changes from the high level to a low level. Then, the PMOS transistor MPT in the logic inverter circuit 10a is turned on, and the clock signal C1 changes from the low level to a high level (the timing TT). As described, C1↑, C2↑, C3↑, and C4↑ (↑ represents the rising edges of the waveforms) occur at the same interval of a time 2tPD2. When the clock signal C1 is synchronized to an external clock Ex, four-phase clock signals having a practical (effective) operating frequency of 1/(2tPD2) are generated as indicated by the operation waveforms in FIG. 2.

Compared with a third example described later, in this example, the gate capacitance and the diffusion layer capacitance are reduced to a smaller value by such amount that each logic inverter circuit has one few PMOS transistor. Further, the clock signal C1 is at a high level during the time when the clock signal C2 is at a high level and the clock signal C3 is at a low level (T2 to T3), and the output terminal OUT of the logic inverter circuit 10a becomes high impedance. At this time, since the output level of the clock signal C1 drops due to the gate capacitance coupling caused by C4↓ (↓ represents the falling edges of the waveforms), the timing of the next C1↓ occurs earlier. Because of these two effects, the first example operates at a higher speed than the third example. Further, there is no part operating faster than the practical (effective) operating frequency of the distribution clocks. Note that, to be precise, it operates at a frequency 4/3 times the practical operating frequency due to an unbalanced duty cycle of the output waveforms.

For instance, when an external power supply voltage is 1.8V, an optimal operating point for the charge pump is approximately VC=0.9V. According to circuit simulations with VC=0.9V, the practical operating frequency is 1.44 GHz with a conventionally configured ring oscillator, and 3.25 GHz with the configuration of the present example. This is because the practical operating frequency of 1/(2tPD2) is a little less than three times higher than that of the conventional example, 1/(6tPD1). Furthermore, compared with the operating frequency 1/(tPD2+tPD3) of the oscillator circuit in Patent Document 1, the operating frequency of the present example is higher since the delay time of the constant current driving inverter is tPD3>>tPD2.

### EXAMPLE 2

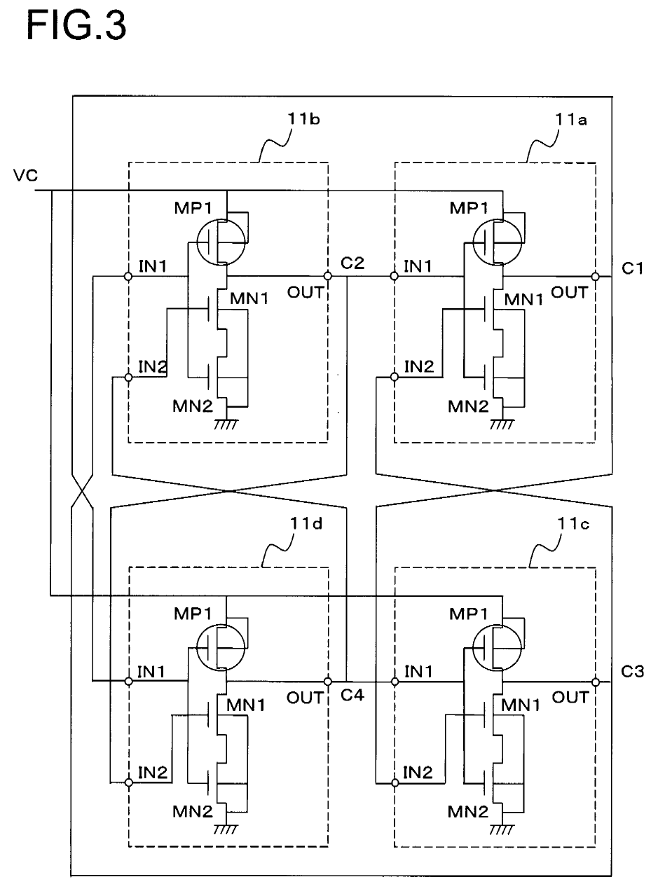

FIG. 3 is a circuit diagram of a clock signal generating circuit relating to a second example of the present invention. In FIG. 3, logic inverter circuits 11a, 11b, 11c, and 11d are configured identically, and compared with the logic inverter circuits in FIG. 1, they differ in that the gate of the PMOS transistor MP1 and the gate of the NMOS transistor MN2 are connected to the input terminal IN1, and that the gate of the NMOS transistor MN1 is connected to the input terminal IN2. In the clock signal generating circuit as described above, taking the charge/discharge time of the diffusion layer capacitances between the NMOS transistors into consideration, the timings of C1↓, C2↓, C3↓, and C4↓ occur earlier, and the timings of C1↑, C2↑, C3↑, and C4↑ are delayed, compared with the configuration in FIG. 1. Therefore, it has an advantage that the duty cycle becomes less unbalanced.

### EXAMPLE 3

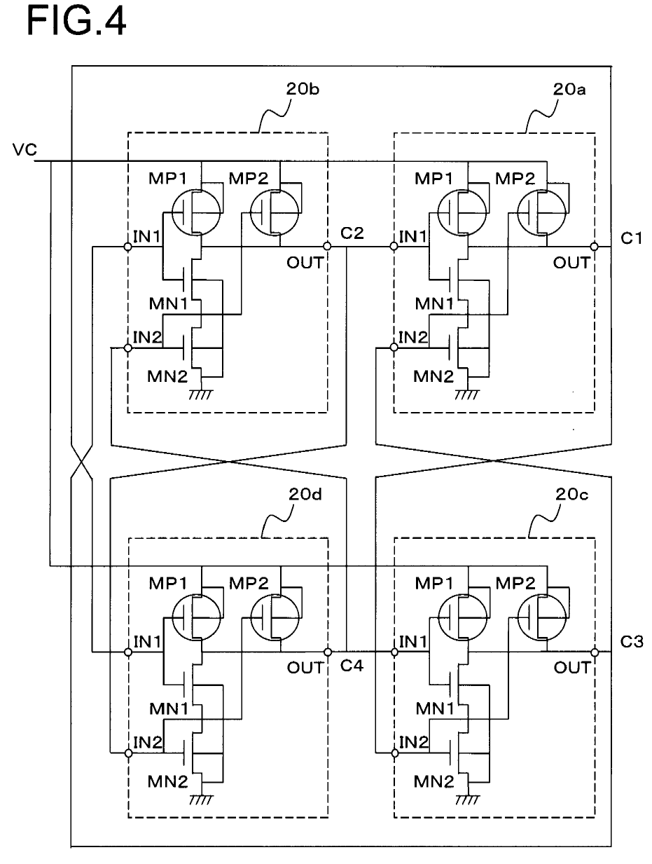

FIG. 4 is a circuit diagram of a clock signal generating circuit relating to the third example of the present invention. In FIG. 4, the symbols same as the ones in FIG. 1 indicates the same things. The clock signal generating circuit in FIG. 4 comprises identically configured logic inverter circuits 20a, 20b, 20c, and 20d. Each of the logic inverter circuits 20a, 20b, 20c, and 20d comprises a PMOS transistor MP2 having the source connected to the power supply VC, the drain connected to the drain of the PMOS transistor MP1, and the gate connected to the input terminal IN2, in addition to the configuration of the logic inverter circuits 10a, 10b, 10c, and 10d shown in FIG. 1. The logic inverter circuits 20a, 20b, 20c, and 20d configured as described above are equivalent to well-known two-input NAND) circuits in the positive logic, and are equivalent to two-input NOR circuit in the negative logic.

Further, the logic inverter circuits 20a, 20b, 20c, and 20d are connected to each other in the same way that the logic inverter circuits 10a, 10b, 10c, and 10d in FIG. 1 are connected. The operating principle and the operating waveforms of the clock signal generating circuit configured as described above are nearly the same as those of the first example. As mentioned earlier, the operating frequency is somewhat lower than the first example, however, it has excellent noise resistance and stability since there is no period during which nodes become high impedance.

The operation of the clock signal generating circuit in FIG. 4 has been simulated under the same conditions as in Example 1, and the practical operating frequency is 2.27 GHz, almost by less twice as high as that of the conventional ring oscillator.

Further, in FIG. 4, the gate of the PMOS transistor MP1 and the gate of the NMOS transistor MN2 may be connected in common to the input terminal IN1, and the gate of the PMOS transistor MP2 and the gate of the NMOS transistor MN1 may be connected in common to the input terminal IN2.

The present invention is suitable for a data transfer circuit built in a semiconductor device such as a high-speed memory.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A clock signal generating circuit comprising:
first to fourth logic inverter circuits; wherein
said first to fourth logic inverter circuits are respectively connected between first and second power supplies, and respectively comprise first and second input terminals and an output terminal;
said output terminal is at a second level when said first input terminal is at a first level, with said output terminal being at the first level when said first and second input terminals are at the second level, in each of said logic inverter circuits; and
first input terminals of said first to fourth logic inverter circuits are connected to output terminals of said second, third, fourth, and first logic inverter circuits respectively, and second input terminals of said first to fourth logic inverter circuits are connected to output terminals of said third, fourth, first, and second logic inverter circuits respectively.

2. The clock signal generating circuit as defined in claim 1, wherein
each of said first to fourth logic inverter circuits comprises a first MOS transistor of a first conductivity type and first and second MOS transistors of a second conductivity type;
a gate of said first MOS transistor of the first conductivity type and a gate of said first or second MOS transistor of the second conductivity type being connected to said first input terminal; a gate of the other MOS transistor of the second conductivity type being connected to said second input terminal; a drain of said first MOS transistor of the first conductivity type and a drain of said first MOS transistor of the second conductivity type being connected to said output terminal; a source of said first MOS transistor of the second conductivity type being connected to a drain of said second MOS transistor of the second conductivity type; a source of said first MOS transistor of the first conductivity type being connected to said first power supply; and a source of said second MOS transistor of the second conductivity type being connected to said second power supply.

3. The clock signal generating circuit as defined in claim 2 wherein each of said first to fourth logic inverter circuits further comprises:
a second MOS transistor of the first conductivity type having its source connected to the source of said first MOS transistor of the first conductivity type, its drain connected to the drain of said first MOS transistor of the first conductivity type, and its gate connected to said second input terminal.

4. A clock signal generating circuit comprising:
first to fourth two-input NAND circuits connected between first and second power supplies; wherein
one of input terminals of each of said first to fourth two-input NAND circuits is connected to an output terminal of said second, third, fourth, and first two-input NAND circuits respectively, and the other input terminal of each of said first to fourth two-input NAND circuits is connected to an output terminal of said third, fourth, first, and second two-input NAND circuits respectively.

5. The clock signal generating circuit as defined in claim 4 wherein said two-input NAND circuits are replaced by two-input NOR circuits.

6. A voltage-controlled oscillator circuit comprising the clock signal generating circuit as defined in claim 1 wherein the oscillation frequency of clock signals generated is varied by controlling a voltage between said first and second power supplies.

7. A voltage-controlled oscillator circuit comprising the clock signal generating circuit as defined in claim 2 wherein the oscillation frequency of clock signals generated is varied by controlling a voltage between said first and second power supplies.

8. A voltage-controlled oscillator circuit comprising the clock signal generating circuit as defined in claim 3 wherein the oscillation frequency of clock signals generated is varied by controlling a voltage between said first and second power supplies.

9. A voltage-controlled oscillator circuit comprising the clock signal generating circuit as defined in claim 4 wherein the oscillation frequency of clock signals generated is varied by controlling a voltage between said first and second power supplies.

10. A voltage-controlled oscillator circuit comprising the clock signal generating circuit as defined in claim 5 wherein the oscillation frequency of clock signals generated is varied by controlling a voltage between said first and second power supplies.
